(19) United States
(12) Patent Application Publication
(10) Pub. No.: US 2025/0321267 A1
(43) Pub. Date: Oct. 16, 2025

(54) VERSATILE INTERPOSER WITH DIAGONAL VIAS FOR TESTING OF INTEGRATED CIRCUIT DEVICES

(71) Applicant: ESSAI, INC., Fremont, CA (US)

(72) Inventors: James Ray Hastings, Fremont, CA (US); Joe Xiao, Fremont, CA (US); Charles William Martin, Fremont, CA (US); Thomas J. Smith, Fremont, CA (US); Quaid Joher Furniturewala, Fremont, CA (US); Brad Emberger, Fremont, CA (US); Albert Charles Seier, Fremont, CA (US)

(21) Appl. No.: 18/641,796

(22) Filed: Apr. 22, 2024

Related U.S. Application Data
(60) Provisional application No. 63/633,671, filed on Apr. 12, 2024.

(51) Int. Cl. G01R 31/28

(52) U.S. Cl. CPC G01R 31/2886; G01R 31/2896

(57) ABSTRACT

High density packaging of multiple semiconductor devices creates very large packages that are demanding to test reliably. The fabrication process causes imperfections such as distortion due to differential thermal expansion rates of attached parts. The loss of flatness creates a problem for reliable connectivity in a test environment leading to frequent wear in test receptacles. A novel approach to mitigate connection uncertainties offers greater reliability with much reduced down time for maintenance.

### CROSS REFERENCE TO RELATED APPLICATION

This Application. (Attorney Docket No. ES-2401-US), entitled “VERSATILE INTERPOSER WITH DIAGONAL VIAS FOR TESTING OF INTEGRATED CIRCUIT DEVICES” claims the benefit and priority of U.S. Provisional Application No. 63/633,671, filed on Apr. 12, 2024 (Attorney Docket No. ES-2401-P), the contents of which is incorporated herein in its entirety by this reference.

### BACKGROUND

The present invention relates to systems and methods for reliable or dependable test tooling for packaged integrated circuit (IC) devices. In particular, improved interconnection structures for IC device test tooling are provided which are tolerant of mechanical irregularities in multi-chip devices.

As large scale integration of semiconductor parts continues, the yield begins to suffer as single substrate semiconductors approach dimensions that encompass faults such as crystalline discontinuities in the material itself. Performance, especially speed, is significantly affected by the proximity of interworking parts and so the mitigation for size limitations of single parts results in multi-chip devices. This includes co-location of parts into a single assembly that increases the capability of the device and also permits volumetric efficiency improvement, where semiconductor components may be stacked vertically atop other semiconductor components. Increasing the number of parts within a device inevitably affects the contact region or area, and can result in mechanical difficulties when multiple semiconductor components are assembled side by side across a comparatively large substrate.

When multiple components are attached to a substrate to create a single device, usually by soldering or possibly brazing, as the assembly cools the different thermal expansion and contraction rates between the components and the substrate material produces significant stress. This stress inevitably distorts the substrate and so a complex warping often results, which means that the bottom of the substrate is no longer flat and the external contact field that is usually brought to the bottom of this substrate now varies in height. Although this variation can be managed in a commercial application of the device, which is a composite of multiple individual integrated circuits contained therein, by using cantilevered contact springs, it is impractical to use a field of such contact springs in a test environment. Contact springs of this kind have a limited lifetime and wear quickly. If a device is simply installed and possibly changed or replaced in a consumer application, there is little risk that the contact springs will fail, but repeated insertion and release of such a device in a testing system has a very low expectation of lifetime, or cycles, before these contact springs fail.

In many cases, pogo-pins (contact pins having variable height based on a spring-loaded center pin) which are used in “bed of nails” test jigs are pressed into service to deal with the vertical positional uncertainty arising from poor flatness of the contact surface of the device under test, but these are costly, prone to damage and can be difficult to service and repair.

A further difficulty is that it is common for new developments to produce repackaged components in a new form factor and it is desirable to use an existing, proven test set-up if possible. A new version of an existing product is often a size reduction exercise and may result in contact points on the new product being closer together than in the original version for which a test jig was designed. In this case it is helpful if, in addition to dealing with mechanical imperfections resulting from such a packaging change, an adapter is constructed. This permits the use of an existing test system which incorporates transformational as well as translational capabilities for matching the disparate connection point geometries.

It is apparent that an urgent need exists for an improved contactor or interposer component capable of achieving superior electrical performance when connecting between contact points on a large subassembly with poor mechanical flatness and existing test jig assemblies. This improved interposer accommodates devices under test that have poor flatness while mapping contact geometries between the device under test and the test jig. A manufacturing process creates an interposer that is versatile and durable while reducing the effects of manufacturing process deficiencies on testing performance, resulting in more dependable and cost-effective testing performance.

### SUMMARY

To achieve the foregoing and in accordance with the present invention, systems and methods for reliable testing of packaged high speed integrated circuit (IC) devices is provided.

In one embodiment, a contact region on one surface of an interposer is arranged so as to be aligned with a corresponding contact region associated with a device under test. On another surface of the interposer, a second contact region is arranged so that it corresponds with a contact region provided on a test board that is connected to a suite of test equipment so that power and signals can be connected to the device under test. This allows the transformation of the contact geography of the device under test to be translated or transformed to match the contact geography present on the test board.

In particular, the contact arrangement on the device under test is not generally the same as the contact arrangement on the test board. An economic advantage is obtained by using an adapter that fits between the device under test and the board that is used to terminate the test equipment being used for the testing. Redesigning a test board, considering the cost of new cabling and the complexity involved in switching between test setups, might negate the financial benefits gained from enhanced device packaging and improved performance of the device under test. Therefore, opting for the reuse of a reliable and proven test jig that incorporates an existing test board is advisable.

The foregoing advantages are achieved by providing connection between the contact points on a device under test and the contact points on the test board by using connecting vias, that are routed between corresponding contact points on the adapter or interposer and are drilled at an angle to the plane of the interposer substrate. This angle may be chosen to suit the displacement needed and may be in the same reference plane as the original contact, such as a plane established by a row of contact points.

In some embodiments, a region of contacts may be displaced linearly so that if the device under test has contacts that are a given distance from a reference plane set by the position of the test board, then the transformed contacts may be simply moved or translated to a different position relative to the reference without changing the contact region geometry. In another embodiment, contact points may be moved so that the distance between contacts is enlarged so as to fit a small contact spacing device to a larger spacing on an existing test board. Transformation in this style relocates and resizes the original geometry of the contacts at the device under test.

Drilling vias at an angle to the usual vertical plane of drilling of the substrate reduces complexity and minimizes the distance between the contact points on the device under test and thus improves the performance of the device testing process. Reduced series resistance and minimized phase shift are significant benefits of the most direct connection path possible by using angularly drilled and plated vias.

By using individual conductive elastomeric pillars that are anisotropic, connectivity is created when the pillars are compressed by insertion of the device to be tested into the test jig. Contrary to using an elastomeric connection strip or sheet, where pressure is applied uniformly, employing individual conductive pillars allows for targeted pressure application. This approach facilitates the testing of large devices, like multi-chip modules, by overcoming the challenges posed by their inherent lack of flatness. Large modules often suffer from uneven surfaces that could compromise the effectiveness of a single layer or sheet, but the use of individual pillars addresses these irregularities, ensuring more reliable testing.

The introduction of complex curvature as a multi-chip device experiences the forces produced by the differential thermal expansion during manufacture requires care to ensure that the interposer is profiled accordingly to match the distortion. Accordingly, the use of individual deformable conductive elements, rather than a consolidated group of elements in a single sheet, confers predictability as well as reliability and durability. Less compliance is then needed from the interconnecting elastomeric conductor assembly to simultaneously make contact to the entire complex curvature.

Note that the various features of the present invention described above may be practiced alone or in combination. These and other features of the present invention will be described in more detail below in the detailed description of the invention and in conjunction with the following figures.

### BRIEF DESCRIPTION OF THE DRAWINGS

In order that the present invention may be more clearly ascertained, some embodiments will now be described, by way of example, with reference to the accompanying drawings, in which:

FIG. 1A illustrates an upper view of an interposer having angled conductive vias and individual anisotropic conductive pads attached to one end of the vias with a contact area spacing appropriate to a device under test, according to one or more aspects of the various embodiments;

FIG. 1B is a bottom view of the interposer of FIG. 1A showing the lateral displacement of the contact areas to correspond to the contact spacing on the test jig, according to one or more aspects of the various embodiments;

FIG. 1C is a cross-sectional view illustrating the profile of a typical internal structure of the interposer of FIG. 1A with angled vias to provide the lateral displacement, according to one or more aspects of the various embodiments;

FIG. 2 shows a close up profile view of an angled via structure having displaced contact areas with deformable anisotropic connection buttons or pillars, according to one or more aspects of the various embodiments;

FIG. 3 illustrates a transformational structure where connections are transformed from one spacing at the upper connection points to a different spacing for the lower connection points using vias with different angles, according to one or more aspects of the various embodiments;

FIG. 4 is a profile view of a device under test connected by upper and lower elastomeric strips and an interposer with angled conductive vias to a test board, according to one or more aspects of the various embodiments;

FIG. 5 shows an interposer structure for use with a distorted or deformed device under test, using anisotropic conductive buttons or pillars to form contact points for the device and the test jig board, according to one or more aspects of the various embodiments; and

FIG. 6 illustrates a version of FIG. 5 that uses a typical elastomeric conductive interconnect in both upper and lower connection areas, according to one or more aspects of the various embodiments.

### DETAILED DESCRIPTION

The present invention will now be described in detail with reference to several embodiments thereof as illustrated in the accompanying drawings. In the following description, numerous specific details are set forth in order to provide a thorough understanding of embodiments of the present invention. It will be apparent, however, to one skilled in the art, that embodiments may be practiced without some or all of these specific details. In other instances, well known process steps and/or structures have not been described in detail in order to not unnecessarily obscure the present invention. The features and advantages of embodiments may be better understood with reference to the drawings and discussions that follow.

Aspects, features and advantages of exemplary embodiments of the present invention will become better understood with regard to the following description in connection with the accompanying drawing(s). It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute and/or sequential terms, such as, for example, “will,” “will not,” “shall,” “shall not,” “must,” “must not,” “first,” “initially,” “next,” “subsequently,” “before,” “after,” “lastly,” and “finally,” are not meant to limit the scope of the present invention as the embodiments disclosed herein are merely exemplary.

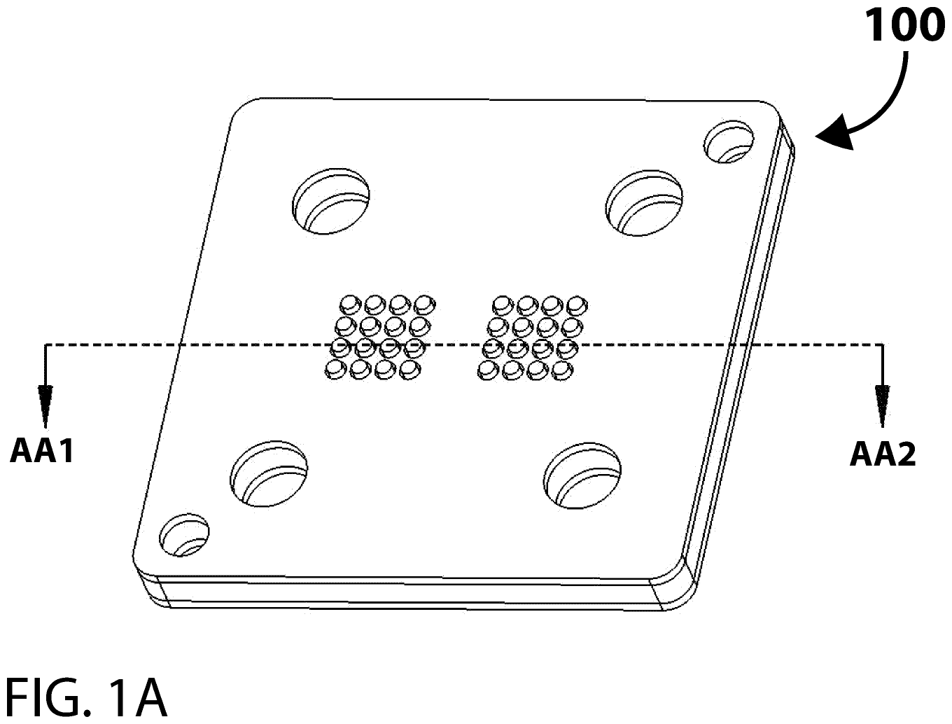

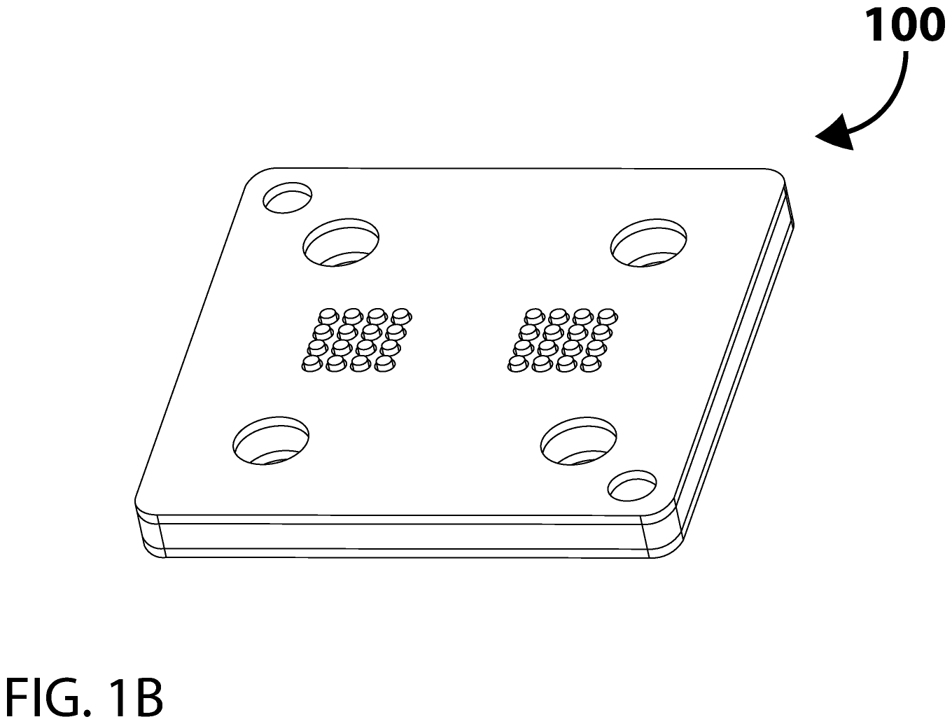

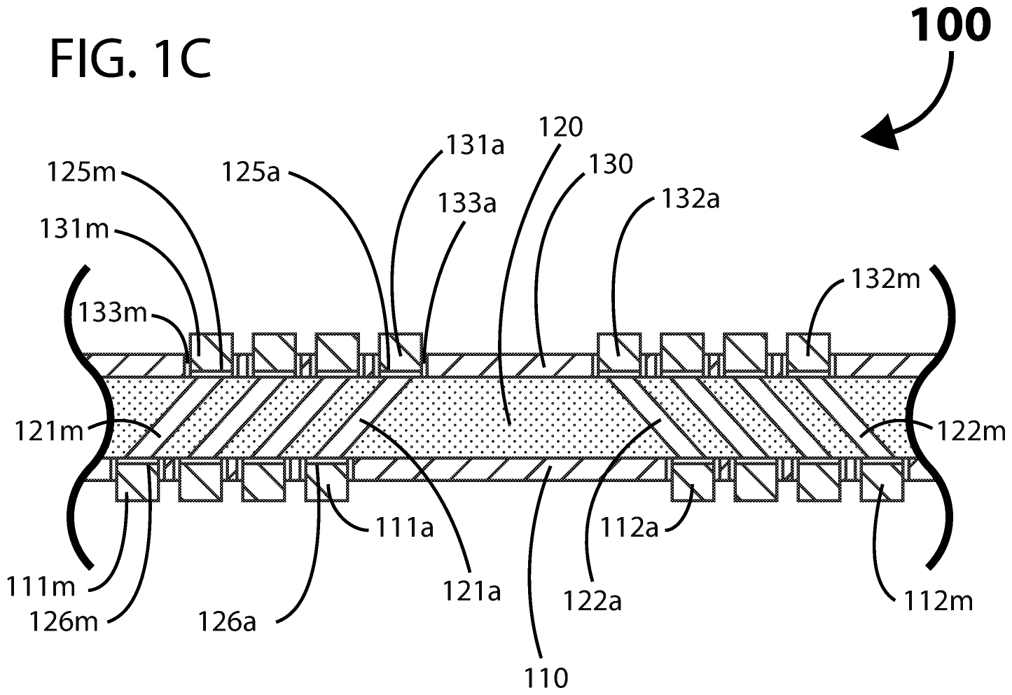

Referring to the drawings, FIGS. 1A and 1B show upper and lower views respectively of an example interposer 100. This translates a particular device contact geometry at the upper side (shown in 1A) to a different geometry at the lower side (shown in 1B). This lower side corresponds to the contact spacing on a test board. This test board connects test signals delivered using cables from the measuring equipment to devices being tested via the interposer. Such interposers are useful because they allow connections to be made to various sized packaged semiconductor devices of the same functional family. Wear from repeated insertion and removal of test devices is thus constrained primarily to the interposer, which interposer can be economically and efficiently changed when wear is observed. The contact points on the interposer are individual contact buttons or pillars made from an anisotropic elastomeric material having well controlled characteristics and chief amongst these is the working compliant range of these buttons. Such conductive elastomeric buttons are commercially available from R&D Interconnect Solutions of Allentown in Pennsylvania, as the Invisipin® product.

The interposer substrate material may be any suitable material having good electrical isolation properties and suitable mechanical properties, such as a glass reinforced polyester e.g. FR4. Printed circuits boards such as the test board that interfaces between the suite of test equipment and a test system designed to accept components for testing is readily made using this material and it can be arranged to include multiple layers of conductors to enable versatile distribution of signals and power to connection points around the board.

Turning now to FIG. 1C, an exemplary intermediator 100 is shown in profile as would be seen along the section line AA1-AA2 indicated at FIG. 1A. In FIG. 1C, the upper part of the intermediator accommodates a device under test (DUT) (not shown) and the lower part fits against a test board (not shown) that interfaces with the test equipment. The figure shows a substrate 120 into which diagonal vias 121a . . . 121m and 122a . . . 122m have been drilled at an angle to the plane of the substrate. For illustration purposes, four angled vias are shown on either side of the middle of the component section shown. It can be seen that the angled vias result in linear displacement of the contact regions relative to the contact region on the opposite side of the intermediator. The vias 121a . . . 121m and 122a . . . 122m are first drilled and then plated through with a conductive material either by electroplating or else by using an electroless plating solution so that there is electrical continuity between the upper and lower ends of each via. Enlargement of the conductor volume in the via is achieved by “plating-up,” where the initial coating is thickened using an electroplating method, or by filling the via with a conductive supplement.

Drilling of the vias 121a . . . 121m and 122a . . . 122m is done at an angle consistent with the material used for the substrate. Precision, multi-axis, numerically controlled drilling equipment allows this operation to be done very accurately and repeatably and a drilling jig is not generally required. If the substrate is layered, it is important that the angle is limited to a value which does not cause delamination. Delamination is the separation of the layers of the substrate and is normally a cause of failure of the substrate foreshadowed by unreliable or intermittent operation. Failure often occurs as a result of cracking of the via somewhere along its length resulting in intermittent operation. If this critical angle is required to be greater than the substrate can withstand, then a different substrate material may be chosen. A number of different engineering plastic materials may be more suitable in some cases, but economic considerations are usually factored into this material choice. Vias may be left as plated or may be filled using a suitable filler material. In one embodiment, a conductive epoxy is used to fill the vias so as to give a reduced electrical resistance as well as providing further mechanical toughness which may mitigate any delamination tendency in some materials. In some embodiments, an epoxy fill of these vias is used simply to give improved mechanical toughness.

The substrate material is further plated on both upper and lower surfaces so as to provide contact pads at the upper and lower ends of each via; in FIG. 1C this contact pad is shown as 125m on the upper surface and 126m on the lower surface. For clarity, two contact pads 125m and 126m are identified in the figure, but these pads are provided at any point where a via terminates and a conductive pillar is to be provided.

Anisotropic conductive pillars, 131a . . . 131m and 132a . . . 132m on the upper surface and conductive pillars 111a . . . 111m and 112a . . . 112m on the lower surface, are soldered to their respective contact pads, e.g., pads 125a . . . 125m and 126a . . . 126m and the other termination points for the vias, which attachment provides a secure mounting at one end of each pillar.

In some embodiments, once the pillars are fitted in place, insulating films 110 and 130 are provided so as to act as a hard stop to limit compression of the pillars. Kapton® is a suitable film material and freely available in a range of thicknesses so that quite precise control of the geometry of the pillars is possible. The films may be provided with an adhesive layer to ease application and securing. The films 110 and 130 are separated from the pillars by small air gaps, e.g., gaps 133a . . . 133m, so that compression of the pillars is done without undue strain. When these anisotropic conductive pillars are squeezed vertically by having a device under test pushed down on top of them, or the corresponding pressure exerted as the intermediator is pressed against the test board upon which it rests, they may tend to swell radially and provision for this alteration in radial dimension should be accommodated; a snug fit of the film would constrain the pillar and force the material of the pillar to move upward so that it could spill out above the film. Such movement is undesirable, destructive and tears the elastomeric material rendering the quality of the contact unrepeatable.

In some embodiments, a solder-mask film is used instead of the Kapton film. Though slightly less durable than Kapton, for a short production test run this offers a relatively simple short term solution. Abrasive wear on the solder-mask film is mitigated by more frequent changeout of the worn part, prior to it causing distress in the testing process. Because solder-mask application is a standard process for production, its inclusion reduces the complexity of manufacture of the interposer at the cost of durability.

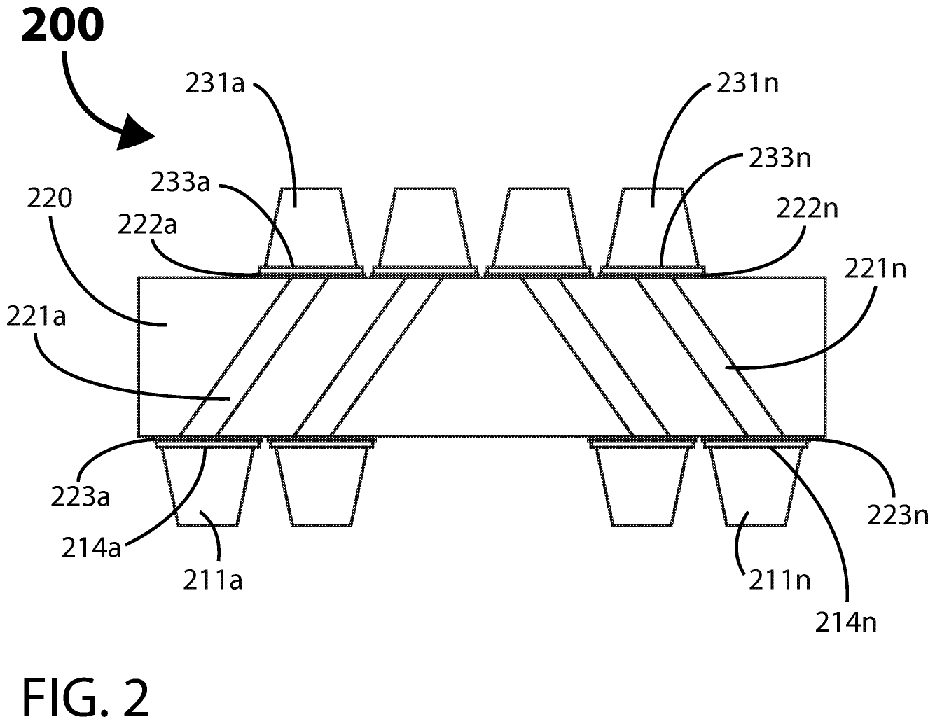

FIG. 2 shows a close up of another embodiment of the interposer 200 without the presence of a hard-stop film. Each of the elastomeric pillars 231a . . . 231n and 211a . . . 211n have respective flanges 233a . . . 233n and 214a . . . 214n that are soldered to contact pads 222a . . . 222n and 223a . . . 223n, respectively. Note that pairs of contact pads 222a & 223a . . . 222n & 223n terminate vias 221a . . . 221n located on top and bottom surfaces respectively of the interposer substrate 220. In some embodiments, the anisotropic pillars are slightly conical so that the resulting draft angle allows for easy release from their manufacturing mold.

Each of the pillars 231a . . . 231n and 211a . . . 211n are bonded at their respective bases to a metallic flange that is very slightly larger in diameter than the base of the pillar. These flanges, e.g., flange 233a, can be 50-60 μm larger than the pillar and for a pillar diameter of 500 μm, the flange diameter can, in some embodiments be about 560 μm. These flanges are made from a solderable material to allow for secure mounting and attachment to their respective contact pads on the substrate 220. The elastomeric pillars suitable for a contact pad pitch of 800 μm, can have a vertical height of 500 μm set on a flange height of 38 μm and can be capable of a working compression range of 200 μm. In the example above, the Kapton® film can be approximately 330-340 μm thick, so that further compression of the elastomeric pillar by a device pressed down on top of the interposer would be prevented. For tighter spacing between these conductive, elastomeric pillars, pitches as low as 400 μm are possible, but the vertical compliance for these parts may be limited to about 90 μm.

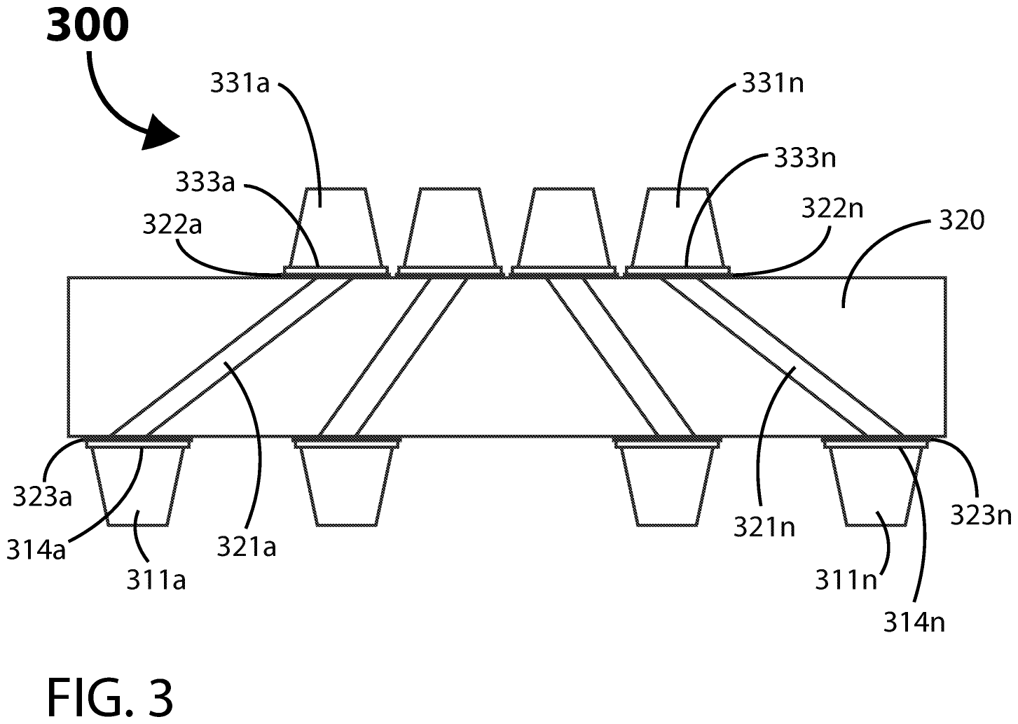

FIG. 3 shows yet another embodiment of an interposer structure 300 where the upper contact pads 322a . . . 322n that terminate the vias 321a . . . 321n are carried through to the lower contact pads 323a . . . 323n that terminate the vias 321a . . . 321n. Each of the elastomeric pillars 331a . . . 331n and 311a . . . 311n have respective flanges 333a . . . 333n and 314a . . . 314n that are soldered to contact pads 322a . . . 322n and 323a . . . 323n, respectively.

The vias 321a . . . 321n are drilled at increasingly oblique angles to the plane of the substrate so that the contact pitch (the distance between contact pads) is not only translated, but is increased. This permits very small pitches on the device under test to be mapped to much larger pitches on the test board which terminates the test equipment, simply by altering the interposer structure. In extreme cases, the elastomeric pillars 331a . . . 331n on the upper surface of substrate 320 could be set for a pitch of 400 μm and with an available compression range of about 90 μm, whereas the elastomeric pillars 311a . . . 311n on the bottom layer could still have a compression range of 200 μm. Although the Kapton® film, used to hard stop limit compression of the pillars, is not shown on this figure, the thickness of the film should be different on the two surfaces.

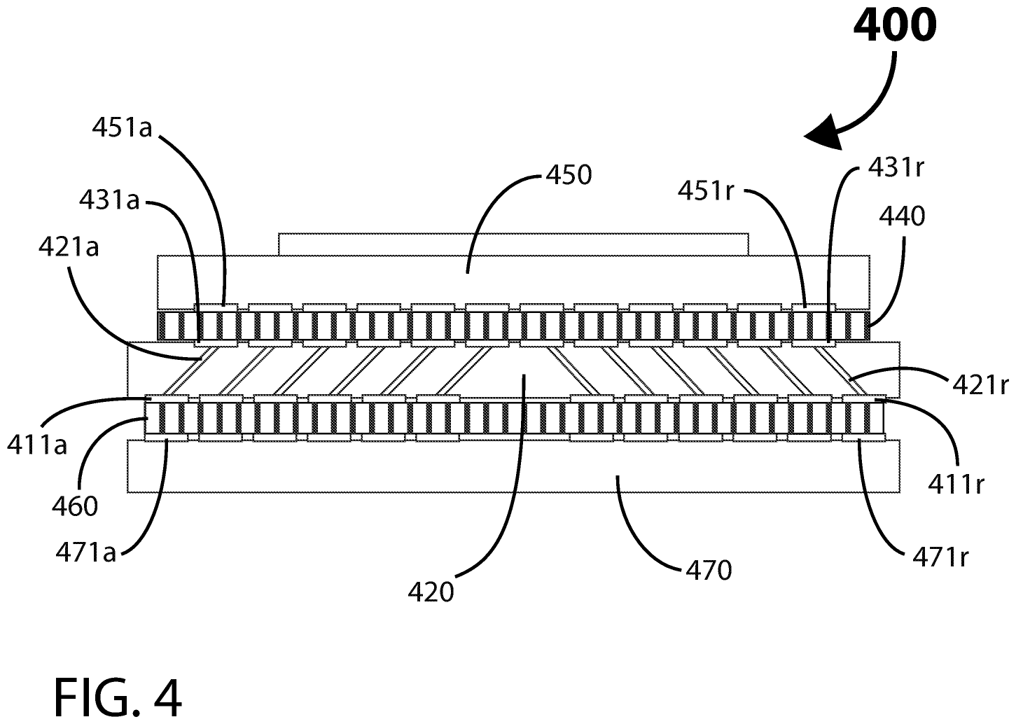

In yet another embodiment as illustrated by the cross-sectional view of FIG. 4, a packaged device under test 450 is connected through elastomeric sheets 440 and 460 via an interposer 420 to the test board 470 that interfaces with the test equipment that is connected using cables. The packaged device(s) under test 450 connect to contact pads 451a . . . 451r that are on the connecting surface of the package containing the device. Elastomeric sheet 440 has alternating elements of conducting and non-conducting elastomer arranged vertically so that connectivity is from top to bottom and there is no conducting channel that runs side to side. It should be clear that the pitch of the elastomeric sheet should be such that at least one conductive element should be available to each intended contact pad.

In FIG. 4 it can be seen on closer inspection that even though the lateral positioning of the device under test may be varied slightly, each contact pad has either two or three conductive paths available. The width of the conductive strips are such that this is typically less than the inter-pad spacing between contact pads to prevent any conductive path between nominally co-planar and adjacent contact pads 431a . . . 431r or 451a . . . 451r for example. Signals and power flow to and from the contact pads 451a . . . 451r on the device under test through the conducting channels in the elastomeric strip 440 to corresponding contact pads 431a . . . 431r on the upper surface of the interposer 420. From here, signal and power flow through angled vias 421a . . . 421r to contact pads 411a . . . 411r on the bottom surface of the interposer, which contact pads are displaced in pitch so as to locate then relative to matching contact pads on the test board 470. Elastomeric strip 460 then connects the contact pads 411a . . . 411r to their corresponding contact pads 471a . . . 471r on the test board.

When the devices under test are large packages such as multi-chip devices, elastomeric connectors arranged as a sheet such as shown in FIG. 4 have substantial surface area and to achieve the connection quality required may demand relatively high forces. This can be disadvantageous. Similarly, although a deformed device package, warped through the effects of differential expansion and contraction during the manufacturing process, can be handled successfully using an elastomeric sheet, when a deformation that exhibits a compound curvature is encountered this becomes problematic. An elastomeric strip, especially when used as a sheet or layer over a broad area of contact points or pads, can undergo creeping and deformation with the repeated application of substantial forces. The inherent design of the strip, which allows for the conductive element's width to expand and contract, facilitates this creeping and introduces strain differentials under asymmetric loads. This issue is commonly observed with packages that are curved or otherwise deformed, highlighting a vulnerability in the use of elastomeric strips for such applications.

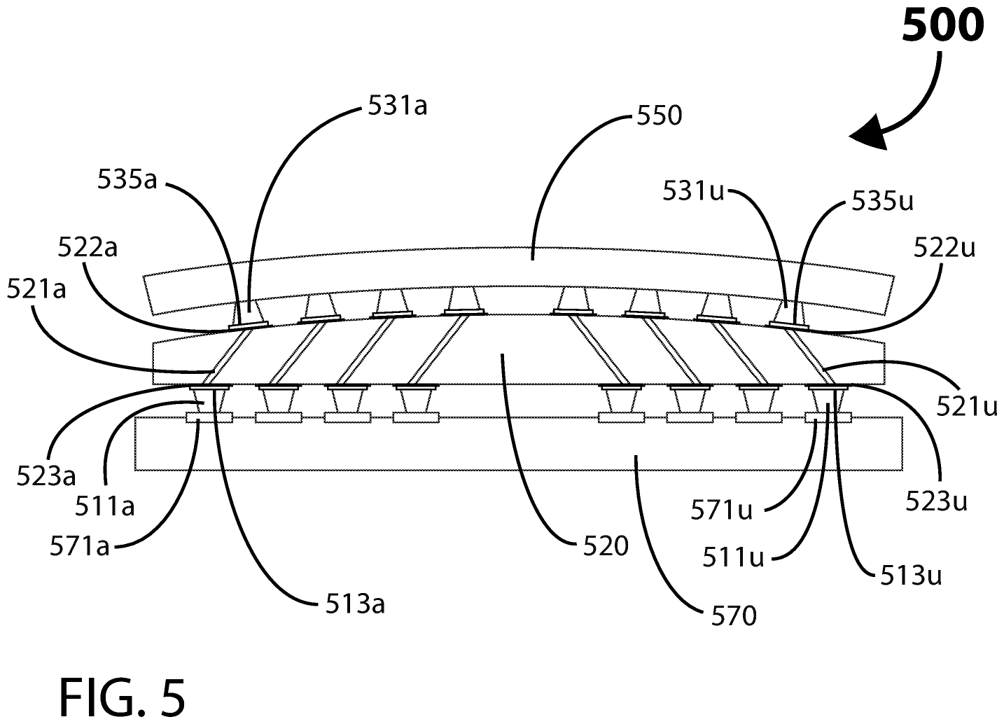

FIG. 5 illustrates a curviform deformation of a device under test 550. Anisotropic elastomeric contact pillars 531a . . . 531u are attached by soldering their flanges 535a . . . 535u to contact pads 522a . . . 522u on the upper surface of interposer 520, which upper surface curvature is matched to the curvature of the device under test. In a stable manufacturing process, the package deformation of the device under test is fortunately quite consistent from item to item, so it is possible to accurately map the surface irregularity and use this information to create a very closely matching curvature for the upper surface of the interposer. This is extendable to compound curved distortion in a package and once the interposer has been formed to a matching shape, the connection detail can be produced. These contact pads 522a . . . 522u terminate vias 521a . . . 521u cut at an angle and terminated by contact pads 523a . . . 523u on the bottom surface of the interposer 520. The bottom surface of the interposer is nominally flat, to match the flatness of the test board 570 which attaches to test equipment using cables. The contact pads 523a . . . 523u on the lower surface of the interposer 520 are located so as to match the positions of the contact pads 571a . . . 571u on the test board 570. Anisotropic elastomeric pillars 511a . . . 511u are attached by soldering their flanges 513a . . . 513u to pads 523a . . . 523u and when the interposer is properly located, they contact their matching contact pads on the test board 570. Note that the hard stop film that is applied to limit the compressive displacement of the pillars is absent from this figure in the interests of clarity.

With this structure that incorporates these single pillars, the force is applied to the pillars and there is no excess residual force applied to any elastomeric parts that do not participate in the transfer of signal or power. This minimizes the stresses placed on the interposer 520 which contributes to reduced wear and improved repeatability and reliability. It also removes almost entirely any deleterious effects such as creep or bunching associated with a single elastomeric strip contact, especially when curvatures are complex.

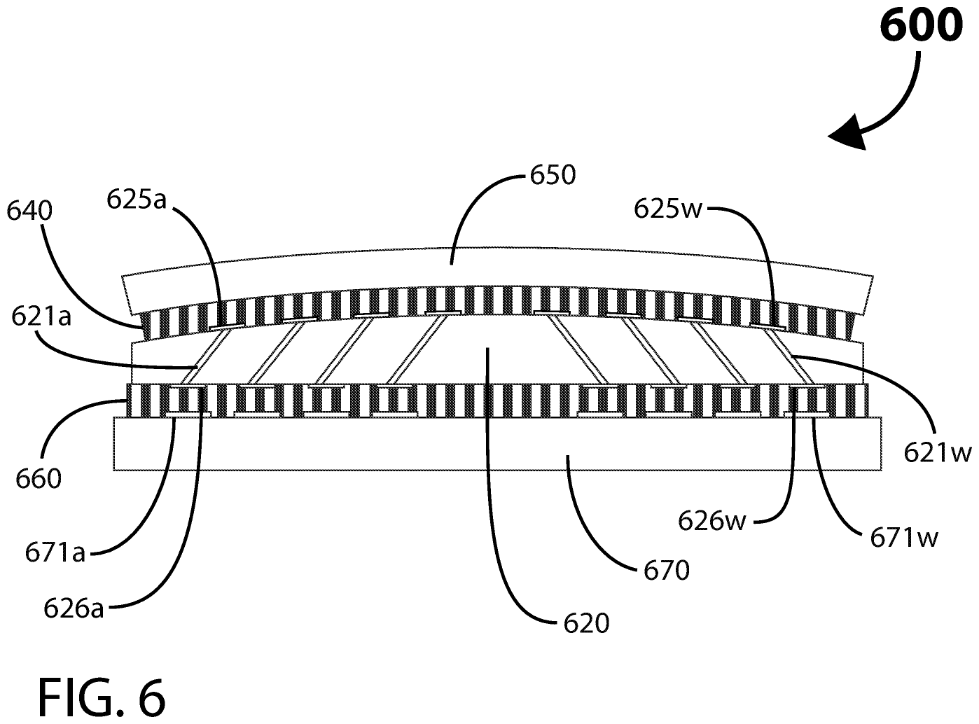

Referring to FIG. 6, a curved interposer is shown in the same way as in FIG. 5. Device under test 650 is connected through elastomeric sheets 640 and 660 via an interposer 620 to the test board 670. Now instead of single pillars being used for contact, an array of conductive strips is used, often as a single sheet or layer to minimize problems in assembling the test set-up. All contact pads, e.g., pad 625a, stand slightly proud of the surface. This is true of the contact pads on the packaged device under test 650 and the test board 670. Upon contact with the elastomeric strip, sheet or layer, the contact pads on both the device under test 650 and the test board 670 compress the elastomeric strip immediately adjacent to that contact pad. This causes the strip to expand as the material is compressed above each pad and causes local buckling in the strip. Any unevenness in the application of force causes the strip to creep and increases wear, thus causing a hot spot, a region of persistent repeated motion, which can abrade the strip and to some degree the contact pads themselves. The limiting compression is reached when all the strip is being compressed in the vertical plane of the strip and the force is applied against the entire surface area of the strip. Again, slanted vias 621a . . . 621w translate the pitch of the contact pads 625a . . . 625w on the upper surface of the interposer that correspond to the contact pitch spacing on the device under test 650 to the pitch spacing of the contact pads 626a . . . 626w on the bottom of the interposer to align with corresponding contact pads 671a . . . 671w on the test board 670.

In sum, the disclosed techniques overcome the limitations of traditional methods by providing diagonal vias to achieve transformation and translation between disparate geometries of device contact arrangements and the contact points on a test board set up. This is accomplished by using an offset interposer that has upper compressible conductive pillars, lower compressible conductive pillars and a substrate with diagonal vias oriented at an angle to the plane of the substrate. The upper pillars are electrically coupled to the contact pads of a device under test (DUT). The lower pillars are electrically coupled to corresponding contact pads on a test circuit board. A subset of the upper pillars are offset with respect to the corresponding subset of the lower pillars. The substrate is located between the upper pillars and the lower pillars. Each of the diagonal vias electrically couples one of the subset of upper pillars to one of the subset of lower pillars. Technical advantages of the disclosed techniques include fewer manufacturing steps in the creation of the interposer, and the ability to accommodate a range of devices with differing contact pad geometries while retaining an existing test board set up by simply exchanging the interposer.

1. In some embodiments, an offset interposer for electrically coupling a Device Under Test (DUT) to a test circuit board, the interposer comprises a plurality of upper compressible conductive pillars configured to be electrically coupled to a corresponding plurality contact pads of the DUT, a plurality of lower compressible conductive pillars configured to be electrically coupled to a corresponding plurality of contact pads of the test circuit board, and wherein a subset of the plurality of upper pillars are offset with respect to a corresponding subset of the plurality of lower pillars, and a substrate having plurality of diagonal vias oriented at an angle to a plane of the substrate, wherein the substrate is located between the plurality of upper pillars and the plurality of lower pillars, and wherein each of the plurality of diagonal vias is configured to electrically couple a corresponding one of the subset of the plurality of upper pillars with a corresponding one of the subset of the plurality of lower pillars.

2. The interposer of clause 1 wherein each of the plurality of diagonal vias is constructed by forming a diagonal through hole and plating the through hole with a conductive material.

3. The interposer of clause 1 or 2 wherein the diagonal through hole is constructed by diagonal drilling or machining.

4. The interposer of clause 1-3 wherein the plated diagonal through hole is reinforced by an epoxy.

5. The interposer of clause 1-4 wherein each of the plurality of upper pillars and each of the plurality of lower pillars are cylindrical.

6. The interposer of clause 1-5 wherein each of the plurality of upper pillars and each of the plurality of lower pillars are tapered.

7. The interposer of clause 1-6 wherein at least one of an upper surface and a lower surface of the substrate is flat.

8. The interposer of clause 1-7 wherein at least one of an upper surface and a lower surface of the substrate is curved to accommodate a corresponding curved surface of the DUT.

9. The interposer of clause 1-8 wherein each of the plurality of diagonal vias are angled between 15 degrees and 60 degrees with respect to the normal to the substrate.

10. The interposer of clause 1-9 wherein a first of the plurality of diagonal vias is angled with respect to a second of the plurality of diagonal vias.

11. In some embodiments, a method for fabricating an interposer having a substrate with a plurality of diagonal vias for electrically interconnecting a device-under-test (DUT) to a test circuit comprises forming a plurality of diagonal through holes in the substrate of the interposer, depositing into the plurality of diagonal through holes a conductive material to form a plurality of conductive diagonal vias, and electrically coupling the plurality of conductive diagonal vias to a corresponding plurality of upper elastomeric pillars and a corresponding plurality of lower elastomeric pillars, wherein the plurality of upper elastomeric pillars are located at an upper surface of the substrate, and wherein the plurality of lower elastomeric pillars are located at a lower surface of the substrate, and wherein the plurality of upper elastomeric pillars and the plurality of lower elastomeric pillars are configured to provide corresponding interconnections between the DUT and the test circuit, respectively.

12. The method of clause 11, ultrasonic machining or laser machining.

13. The method of clause 11 or 12 wherein the conductive material is metallic.

14. The method of clause 11-13 wherein the conductive material is embedded in a binder.

15. The method of clause 11-14 the binder is an epoxy material.

16. The method of clause 11-15 wherein each of the plurality of upper pillars and each of the plurality of lower pillars are cylindrical.

17. The method of clause 11-16 wherein each of the plurality of upper pillars and each of the plurality of lower pillars are tapered.

18. The method of clause 11-17 wherein at least one of an upper surface and a lower surface of the substrate is curved to accommodate a corresponding curved surface of the DUT.

19. The method of clause 11-18 wherein each of the plurality of diagonal vias are angled between 15 degrees and 60 degrees with respect to the normal to the substrate.

20. The method of clause 11-19 wherein a first of the plurality of diagonal vias is angled with respect to a second of the plurality of diagonal vias.

Many modifications and permutations of the above described embodiments are also possible and are contemplated in accordance with the present invention. For example, to displace the contact pads on the bottom of an interposer, the contact pads may be placed asymmetrically at the end of a via so that the via connects to one edge of the contact pad instead of the central region.

While this invention has been described in terms of several embodiments, there are alterations, modifications, permutations, and substitute equivalents, which fall within the scope of this invention. For example, many modifications are possible and the above described features from the various embodiments can be useful alone or in combination. Although sub-section titles have been provided to aid in the description of the invention, these titles are merely illustrative and are not intended to limit the scope of the present invention.

It should also be noted that there are many alternative ways of implementing the methods and apparatuses of the present invention. It is therefore intended that the following appended claims be interpreted as including all such alterations, modifications, permutations, and substitute equivalents as fall within the true spirit and scope of the present invention.

What is claimed is:

1. An offset interposer for electrically coupling a Device Under Test (DUT) to a test circuit board, the interposer comprising:
a plurality of upper compressible conductive pillars configured to be electrically coupled to a corresponding plurality contact pads of the DUT;
a plurality of lower compressible conductive pillars configured to be electrically coupled to a corresponding plurality of contact pads of the test circuit board, and wherein a subset of the plurality of upper pillars are offset with respect to a corresponding subset of the plurality of lower pillars; and
a substrate having plurality of diagonal vias oriented at an angle to a plane of the substrate, wherein the substrate is located between the plurality of upper pillars and the plurality of lower pillars, and wherein each of the plurality of diagonal vias is configured to electrically couple a corresponding one of the subset of the plurality of upper pillars with a corresponding one of the subset of the plurality of lower pillars.

2. The interposer of claim 1 wherein each of the plurality of diagonal vias is constructed by forming a diagonal through hole and plating the through hole with a conductive material.

3. The interposer of claim 2 wherein the diagonal through hole is constructed by diagonal drilling or machining.

4. The interposer of claim 2 wherein the plated diagonal through hole is reinforced by an epoxy.

5. The interposer of claim 1 wherein each of the plurality of upper pillars and each of the plurality of lower pillars are cylindrical.

6. The interposer of claim 1 wherein each of the plurality of upper pillars and each of the plurality of lower pillars are tapered.

7. The interposer of claim 1 wherein at least one of an upper surface and a lower surface of the substrate is flat.

8. The interposer of claim 1 wherein at least one of an upper surface and a lower surface of the substrate is curved to accommodate a corresponding curved surface of the DUT.

9. The interposer of claim 1 wherein each of the plurality of diagonal vias are angled between 15 degrees and 60 degrees with respect to the normal to the substrate.

10. The interposer of claim 1 wherein a first of the plurality of diagonal vias is angled with respect to a second of the plurality of diagonal vias.

11. A method for fabricating an interposer having a substrate with a plurality of diagonal vias for electrically interconnecting a device-under-test (DUT) to a test circuit, the method comprising:
forming a plurality of diagonal through holes in the substrate of the interposer;
depositing into the plurality of diagonal through holes a conductive material to form a plurality of conductive diagonal vias; and
electrically coupling the plurality of conductive diagonal vias to a corresponding plurality of upper elastomeric pillars and a corresponding plurality of lower elastomeric pillars, wherein the plurality of upper elastomeric pillars are located at an upper surface of the substrate, and wherein the plurality of lower elastomeric pillars are located at a lower surface of the substrate, and wherein the plurality of upper elastomeric pillars and the plurality of lower elastomeric pillars are configured to provide corresponding interconnections between the DUT and the test circuit, respectively.

12. The method of claim 11 wherein herein the diagonal through holes are formed by one or more of drilling, ultrasonic machining or laser machining.

13. The method of claim 11 wherein the conductive material is metallic.

14. The method of claim 11 wherein the conductive material is embedded in a binder.

15. The method of claim 14 the binder is an epoxy material.

16. The method of claim 11 wherein each of the plurality of upper pillars and each of the plurality of lower pillars are cylindrical.

17. The method of claim 11 wherein each of the plurality of upper pillars and each of the plurality of lower pillars are tapered.

18. The method of claim 11 wherein at least one of an upper surface and a lower surface of the substrate is curved to accommodate a corresponding curved surface of the DUT.

19. The method of claim 11 wherein each of the plurality of diagonal vias are angled between 15 degrees and 60 degrees with respect to the normal to the substrate.

20. The method of claim 11 wherein a first of the plurality of diagonal vias is angled with respect to a second of the plurality of diagonal vias.
